(19) United States
(12) Patent Application Publication
(10) Pub. No.: US 2025/0365921 A1
(43) Pub. Date: Nov. 27, 2025

(54) MANUFACTURING METHOD OF SEMICONDUCTOR DEVICE

(71) Applicant: NANYA TECHNOLOGY CORPORATION, New Taipei city (TW)

(72) Inventors: Jeng-Yu CHIANG, New Taipei City (TW); Tzu-Li TSENG, New Taipei City (TW)

(21) Appl. No.: 18/671,617

(22) Filed: May 22, 2024

(51) Int. Cl. H10B 12/00

(52) U.S. Cl. CPC H10B 12/053

(57) ABSTRACT

In accordance with an aspect of the present disclosure, a manufacturing method of a semiconductor device is provided. A semiconductor structure is provided, wherein the semiconductor structure includes a substrate; a bottom conductive layer in an active region; a top conductive layer on the bottom conductive layer; a cover layer on the substrate; and a lining layer surrounding the top conductive layer and covering the cover layer. A first etching process is performed to remove a first portion of the top conductive layer and the lining layer located on the cover layer. A sacrificial film is formed on the top conductive layer and the cover layer, wherein the sacrificial film includes carbon and fluorine. A second etching process is performed to remove the sacrificial film and a second portion of the top conductive layer. And a cap layer on the top conductive layer and the cover layer.

### FIELD OF INVENTION

The present disclosure relates to a manufacturing method of semiconductor device. More particularly, the present disclosure relates to a method that may enhance the temperature sensitivity of word line.

### DESCRIPTION OF RELATED ART

In recent decades, demand to storage capability has increased as electronic products continue to improve. In order to increase storage capability of a memory device (e.g., a DRAM device), more memory cells are integrated in the memory device. As the integration level increases, fabrication process of the memory device become much more complicated, and process window become rather narrow. As the process window becoming narrower, it is hard to adjust the word line dry etching depth.

Accordingly, the present disclosure provides a manufacturing method of semiconductor device, wherein the temperature sensitivity of word line may be increased.

### SUMMARY

In accordance with an aspect of the present disclosure, a manufacturing method of a semiconductor device is provided. The method include following steps. A semiconductor structure is provided, wherein the semiconductor structure includes a substrate; an active region in the substrate; a bottom conductive layer in the active region; a top conductive layer on the bottom conductive layer; a cover layer on the substrate; and a lining layer surrounding the top conductive layer and covering the cover layer. A first etching process is performed to remove a first portion of the top conductive layer and the lining layer located on the cover layer. A sacrificial film is formed on the top conductive layer and the cover layer, wherein the sacrificial film includes carbon and fluorine. A second etching process is performed to remove the sacrificial film and a second portion of the top conductive layer. And a cap layer on the top conductive layer and the cover layer.

According to some embodiments of the present disclosure, wherein a first etchant used in the first etching process includes chlorine (Cl₂).

According to some embodiments of the present disclosure, wherein a precursor for forming the sacrificial film includes hexafluorobutadiene (C₄F₆).

According to some embodiments of the present disclosure, wherein a second etchant used in the second etching process includes sulfur hexafluoride (SF₆).

According to some embodiments of the present disclosure, wherein the bottom conductive layer includes TiN.

According to some embodiments of the present disclosure, wherein the first etching process is performed at a temperature of 20° C. to 40° C.

According to some embodiments of the present disclosure, wherein the sacrificial film is formed at a temperature of 20° C. to 40° C.

According to some embodiments of the present disclosure, wherein the second etching process is performed at a temperature of 20° C. to 60° C.

In accordance with an aspect of the present disclosure, a manufacturing method of a semiconductor device is provided. The method include following steps. A semiconductor wafer having a first region and a second region is provided, wherein the semiconductor wafer includes a substrate; a bottom conductive layer in the substrate; a top conductive layer on the bottom conductive layer; and a cover layer on the substrate. A first etching process is performed to remove a portion of the top conductive layer. A sacrificial film is formed on the top conductive layer and the cover layer, wherein the sacrificial film includes carbon and fluorine. A second etching process is performed to remove the sacrificial film and a portion of the top conductive layer, wherein a first temperature of the first region of the semiconductor wafer is higher than a second temperature of the second region of the semiconductor wafer, such that a first etching depth of the top conductive layer of the first region is larger than a second etching depth of the top conductive layer of the second region. A cap layer is formed on the top conductive layer and the cover layer.

According to some embodiments of the present disclosure, wherein a first etchant used in the first etching process includes chlorine (Cl₂).

According to some embodiments of the present disclosure, wherein a precursor for forming the sacrificial film includes hexafluorobutadiene (C₄F₆).

According to some embodiments of the present disclosure, wherein a second etchant used in the second etching process includes sulfur hexafluoride (SF₆).

According to some embodiments of the present disclosure, wherein the first region of the semiconductor wafer is an array region and the second region of the semiconductor wafer is a peripheral region.

According to some embodiments of the present disclosure, wherein the first temperature of the first region of the semiconductor wafer is in a range of 50° C. to 60° C.

According to some embodiments of the present disclosure, wherein the second temperature of the second region of the semiconductor wafer is in a range of 20° C. to 40° C.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematic diagram of a semiconductor device, in accordance with some embodiments;

FIG. 2 is a cross-sectional view schematic diagram of a semiconductor device after performing a first etching process, in accordance with some embodiments;

FIG. 3 is a cross-sectional view schematic diagram a semiconductor device after forming a sacrificial film, in accordance with some embodiments;

FIG. 4 is a cross-sectional view schematic diagram of a semiconductor device after performing a second etching process, in accordance with some embodiments;

FIG. 5 is a cross-sectional view schematic diagram of a semiconductor device after forming a cap layer, in accordance with some embodiments; and

FIG. 6 is a top view schematic diagram of a semiconductor device, in accordance with some embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

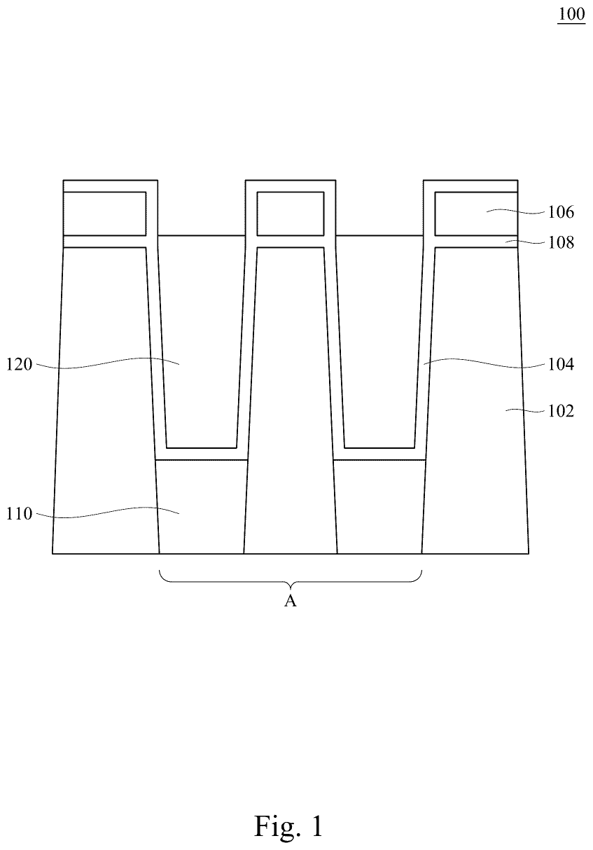

FIG. 1 is cross-sectional view schematic diagram a semiconductor device 100, in accordance with some embodiments. The semiconductor device 100 can be applied in an integrated circuit (IC) or a part thereof, such as a logic circuit, a resistor, a capacitor, an inductor, a memory (such as a dynamic random access memory (DRAM)), and the like. It should be understood that some elements of the semiconductor device 100 are not shown in FIGS. 1-6 to simplify the drawings, and that additional elements may be included in other embodiments of the semiconductor device 100.

The semiconductor device 100 includes a substrate 102, an active region A, a lining layer 104, a cover layer 106, a oxide layer 108, a bottom conductive layer 110, and a top conductive layer 120. Referring to FIG. 1, the active region A is located in the substrate 102. The bottom conductive layer 110 is located in the active region A. The top conductive layer 120 is located on the bottom conductive layer 110. The cover layer 106 is located on the substrate 102. The lining layer 104 surrounding the top conductive layer 120 and covering the cover layer 106. The oxide layer 108 is located between the substrate 102 and the cover layer 106.

In some embodiments, the substrate 102 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 102 can be doped (eg, containing p-type or n-type dopants) or undoped. In some embodiments, the semiconductor material of the substrate 102 may include silicon, germanium, compound semiconductors (including silicon carbide, gallium arsenide, gallium phosphide, indium phosphide, indium arsenide, and/or indium antimonide), alloy semiconductors or a combination thereof. The substrate 102 can also be formed of other materials, such as sapphire, indium tin oxide, and the like.

In some embodiments, the lining layer 104 may include oxide and is formed by suitable deposition process. In some embodiments, the cover layer 106 may include nitride and is formed by suitable deposition process. In some embodiments, the oxide layer 108 and the lining layer 104 may include same material. For example, the lining layer 104, the cover layer 106, and the oxide layer 108 is formed by chemical vapor deposition (CVD), atomic layer deposition (ALD), or physical vapor deposition (PVD).

In some embodiments, the bottom conductive layer 110 is formed by chemical vapor deposition (CVD), atomic layer deposition (ALD), or physical vapor deposition (PVD). In some embodiments, the bottom conductive layer 110 may include titanium nitride (TiN). In some embodiments, the top conductive layer 120 is formed by chemical vapor deposition (CVD), atomic layer deposition (ALD), or physical vapor deposition (PVD). In some embodiments, the top conductive layer 120 may include poly silicon. The bottom conductive layer 110 and the top conductive layer 120 may include suitable conductive material such as metal, metal alloy, metal nitride, or the like. The bottom conductive layer 110 and the top conductive layer 120 may include different materials.

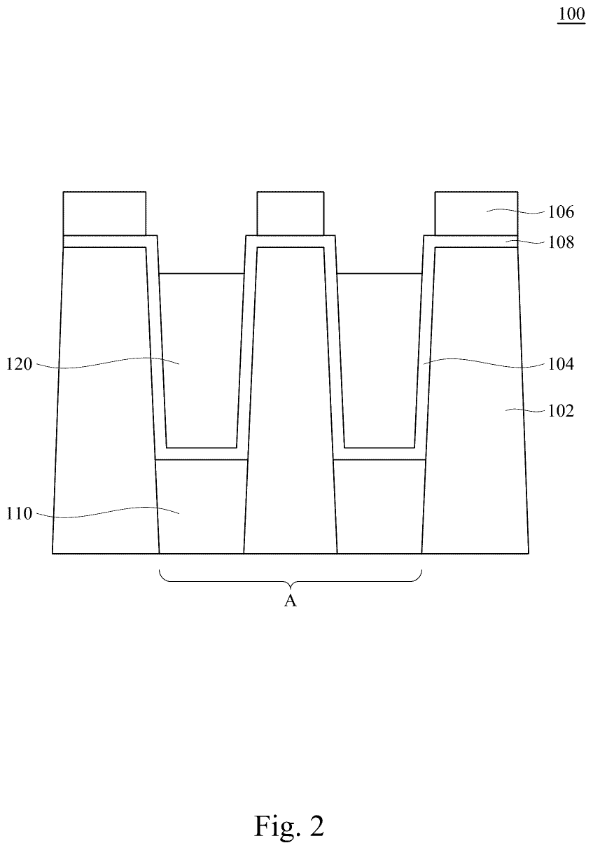

Referring to FIG. 2, a first etching process is performed to remove a first portion of the top conductive layer 120 and the lining layer 104 located on the cover layer 106. In other words, the top surface of the top conductive layer 120 is removed. The lining layer 104 located on the top surface of the cover layer 106 is removed, and the lining layer 104 located on the side portion of the cover layer 106 is also removed. In some embodiments, the first etching process is a gas etching process. In some embodiments, the first gas etchant includes chlorine (Cl₂). In some embodiments, the first etching process is performed at a temperature of 20° C. to 40° C. For example, the first etching process is performed at a room temperature.

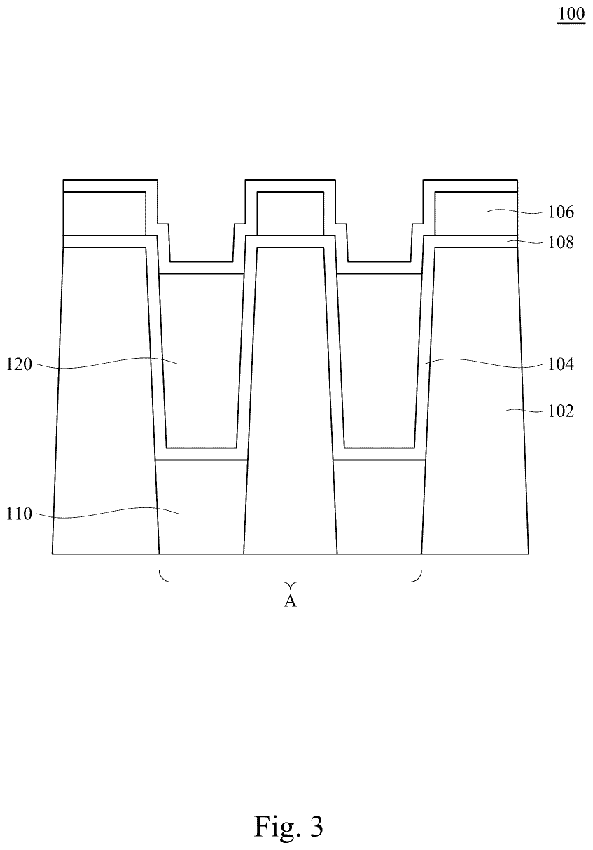

Referring to FIG. 3, a sacrificial film 130 is formed on the top conductive layer 120 and the cover layer 106. In other words, the sacrificial film 130 is formed on the top surface of the top conductive layer 120. The sacrificial film 130 is formed on the top surface and the side portion of the cover layer. In some embodiments, the sacrificial film 130 comprises carbon and fluorine. In some embodiments, the sacrificial film 130 is formed by chemical vapor deposition (CVD), atomic layer deposition (ALD), or physical vapor deposition (PVD). In some embodiments, a precursor for forming the sacrificial film comprises hexafluorobutadiene (C₄F₆). In some embodiments, the sacrificial film 130 is formed at a temperature of 20° C. to 40° C. For example, the sacrificial film 130 is formed at a temperature same as the first etching process is performed.

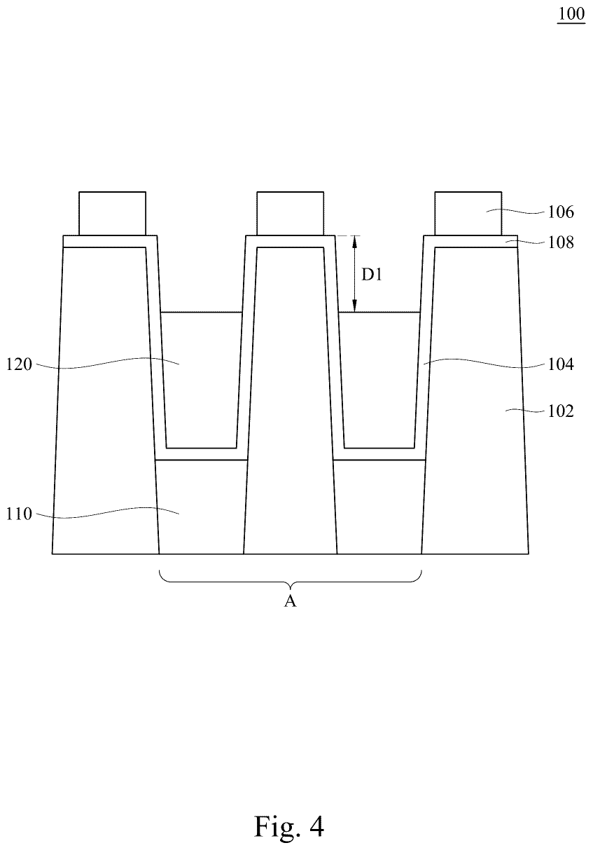

Referring to FIG. 4, a second etching process is performed to remove the sacrificial film 130 and a second portion of the top conductive layer 120. After the second etching process, the top conductive layer reaches the etching depth D1. The etching depth D1 refers to the length from the top surface of the oxide layer 108 to the top surface of the top conductive layer 120. In some embodiments, the second etching process is a gas etching process. In some embodiments, the second gas etchant includes sulfur hexafluoride (SF₆). In some embodiments, the second etching process is performed at a temperature of 20° C. to 60° C. For example, when the first etching process is performed at 25° C., the second etching process may be performed at 50° C. For example, when the first etching process is performed at 30° C., the second etching process may be performed at 30° C.

The second etching process is performed at a temperature based on the predetermined etching depth D1. After forming the sacrificial film 130, the temperature sensitivity of the surface of the semiconductor device 100 is increased. Therefore, it is possible to adjust the temperature of the second etching process to adjust the etching depth D1 of the top conductive layer 120. After forming the sacrificial film 130, when the second etching process is performed in higher temperature within the same time, the etching depth D1 becomes larger.

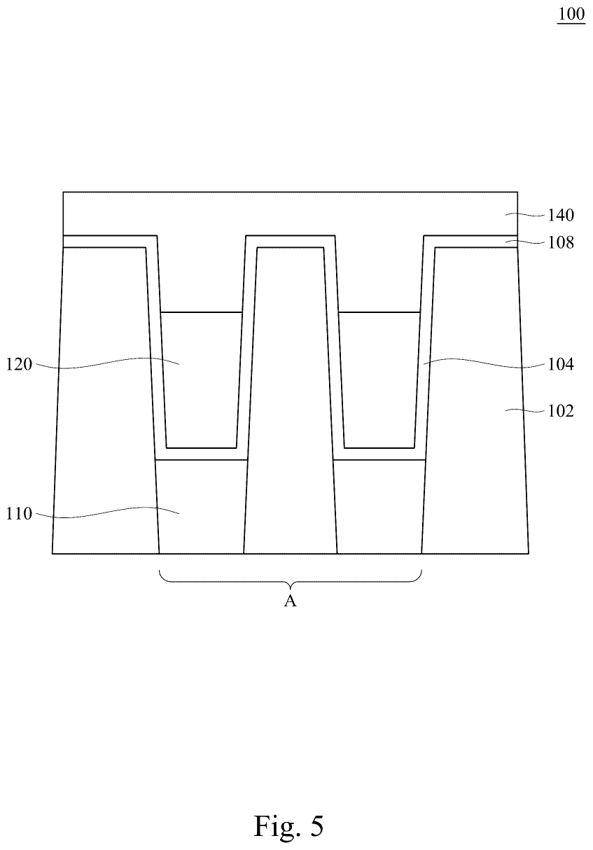

Referring to FIG. 5, a cap material is deposited on the top conductive layer 120 and above the cover layer 106. In some embodiments, the cap material may be formed by any suitable deposition process such as chemical vapor deposition (CVD), atomic layer deposition (ALD), or physical vapor deposition (PVD). Next, a portion of the cap material is removed to form a cap layer 140 on the top conductive layer 120. In some embodiments, removing the portion of the cap material includes performing a planarization process, for example, a chemical mechanical planarization (CMP) process. In some embodiments, the cap layer 140 and the cover layer 106 include same material. For example, the cap layer 140 and the cover layer 106 both include nitride.

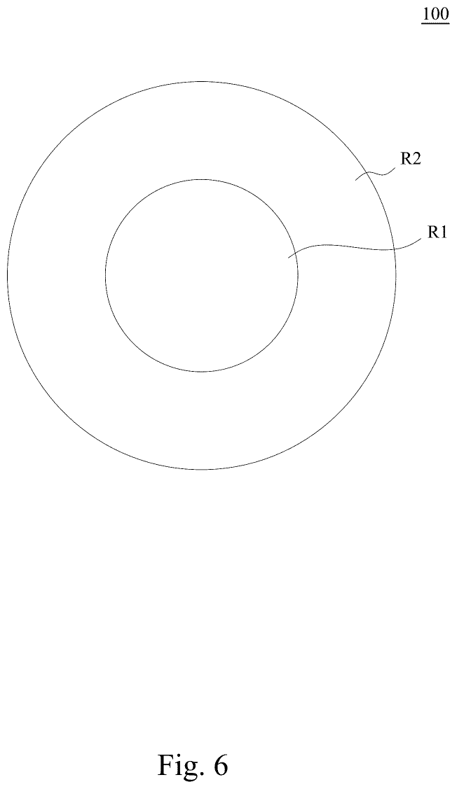

As described above, after the sacrificial film 130 is formed, the temperature sensitivity of the semiconductor device is increased. Therefore, in the second etching process, the temperature of the semiconductor device 100 can be locally adjusted to adjust the etching depth D1 of the top conductive layer 120. Referring to FIG. 6, FIG. 6 provides a top view schematic diagram of the semiconductor device 100. In some embodiments, the semiconductor device 100 is a semiconductor wafer. The semiconductor wafer includes a first region R1 and a second region R2. In some embodiments, the first region R1 is the array region, and the second region R2 is the peripheral region.

In some embodiments, during the second etching process, a first temperature of the first region R1 of the semiconductor wafer is higher than a second temperature of the second region R2 of the semiconductor wafer. For example, the first temperature of the first region of the semiconductor wafer is in a range of 50° C. to 60° C., and the second temperature of the second region of the semiconductor wafer is in a range of 20° C. to 40° C.

In some embodiments, during the second etching process, a first temperature of the first region R1 of the semiconductor wafer is equal to a second temperature of the second region R2 of the semiconductor wafer. For example, the first temperature of the first region of the semiconductor wafer is 30° C., and the second temperature of the second region of the semiconductor wafer is in a range of 30° C.

In some embodiments, during the second etching process, a first temperature of the first region R1 of the semiconductor wafer is lower than a second temperature of the second region R2 of the semiconductor wafer. For example, the first temperature of the first region of the semiconductor wafer is 25° C., and the second temperature of the second region of the semiconductor wafer is in a range of 40° C. As described above, it is possible to adjust the temperature of the second etching process locally to adjust the word line dry etching depth of a local region.

Regarding etching depth D1 after performing the second etching process of the embodiment of the present disclosure and comparison groups in different temperatures, please refer to Table 1 below. The comparison groups do not include the step of forming the sacrificial film 130, and the other step are the same as the embodiments of the present disclosure. As shown in Table 1, in the comparison groups, the temperature change of the second etching process has little impact on the etching depth D1. In the embodiments of the present disclosure, when the temperature of the second etching process increases, it can be obviously seen that the etching depth D1 becomes larger. When the temperature of second etching process is 20° C. the etching depth D1 of the top conductive layer is 60.4 nm, and when the temperature of second etching process is 60° C. the etching depth D1 of the top conductive layer is 71.0 nm. It is clear that the temperature sensitive of the semiconductor device is increased after forming the sacrificial film 130.

TABLE 1

| | Temperature | Mean of etching depth D1 |
|---|---|---|
| Comparison groups | 20° C. | 60.0 nm |
| | 40° C. | 60.5 nm |
| | 60° C. | 60.6 nm |
| Embodiments | 20° C. | 60.4 nm |
| | 40° C. | 67.1 nm |
| | 60° C. | 71.0 nm |

According to the above embodiments of the present disclosure, the present disclosure provides a manufacturing method of semiconductor device. With the method provided in the present disclosure, by forming the sacrificial film, the temperature sensitivity of word line is increased, so it is easier to adjust the word line dry etching depth. According to the above embodiments of the present disclosure, it is also possible to adjust the temperature of the second etching process locally to adjust the word line dry etching depth of a local region.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims.

What is claimed is:

1. A manufacturing method of semiconductor device, comprising:
providing a semiconductor structure, wherein the semiconductor structure comprises:
a substrate;
an active region in the substrate;
a bottom conductive layer in the active region;
a top conductive layer on the bottom conductive layer;
a cover layer on the substrate; and
a lining layer surrounding the top conductive layer and covering the cover layer;
performing a first etching process to remove a first portion of the top conductive layer and the lining layer located on the cover layer;
forming a sacrificial film on the top conductive layer and the cover layer, wherein the sacrificial film comprises carbon and fluorine;
performing a second etching process to remove the sacrificial film and a second portion of the top conductive layer; and
forming a cap layer on the top conductive layer and the cover layer.

2. The method of claim 1, wherein a first etchant used in the first etching process comprises chlorine (Cl₂).

3. The method of claim 1, wherein a precursor for forming the sacrificial film comprises hexafluorobutadiene (C₄F₆).

4. The method of claim 1, wherein a second etchant used in the second etching process comprises sulfur hexafluoride (SF₆).

5. The method of claim 1, wherein the bottom conductive layer comprises TiN.

6. The method of claim 1, wherein the first etching process is performed at a temperature of 20° C. to 40° C.

7. The method of claim 1, wherein the sacrificial film is formed at a temperature of 20° C. to 40° C.

8. The method of claim 1, wherein the second etching process is performed at a temperature of 20° C. to 60° C.

9. A manufacturing method of semiconductor device, comprising:
providing a semiconductor wafer having a first region and a second region, wherein the semiconductor wafer comprises:
a substrate;
a bottom conductive layer in the substrate;
a top conductive layer on the bottom conductive layer; and
a cover layer on the substrate;
performing a first etching process to remove a portion of the top conductive layer;
forming a sacrificial film on the top conductive layer and the cover layer, wherein the sacrificial film comprises carbon and fluorine;
performing a second etching process to remove the sacrificial film and a portion of the top conductive layer, wherein a first temperature of the first region of the semiconductor wafer is higher than a second temperature of the second region of the semiconductor wafer, such that a first etching depth of the top conductive layer of the first region is larger than a second etching depth of the top conductive layer of the second region; and
forming a cap layer on the top conductive layer and the cover layer.

10. The method of claim 9, wherein a first etchant used in the first etching process comprises chlorine (Cl₂).

11. The method of claim 9, wherein a precursor for forming the sacrificial film comprises hexafluorobutadiene (C₄F₆).

12. The method of claim 9, wherein a second etchant used in the second etching process comprises sulfur hexafluoride (SF₆).

13. The method of claim 9, wherein the first region of the semiconductor wafer is an array region and the second region of the semiconductor wafer is a peripheral region.

14. The method of claim 9, wherein the first temperature of the first region of the semiconductor wafer is in a range of 50° C. to 60° C.

15. The method of claim 9, wherein the second temperature of the second region of the semiconductor wafer is in a range of 20° C. to 40° C.
